(19) United States
(12) Patent Application Publication
(10) Pub. No.: US 2025/0054803 A1
(43) Pub. Date: Feb. 13, 2025

(54) SUBSTRATE PROCESSING DEVICE AND SUBSTRATE PROCESSING METHOD FOR IMPROVING SUBSTRATE STICKINESS PHENOMENON

(71) Applicant: PSK Holdings Inc., Hwaseong-si (KR)

(72) Inventor: Gunwoo LEE, Osan-si (KR)

(73) Assignee: PSK Holdings Inc., Hwaseong-si (KR)

(21) Appl. No.: 18/926,236

(22) Filed: Oct. 24, 2024

Related U.S. Application Data
(63) Continuation of application No. PCT/KR2022/009901, filed on Jul. 8, 2022.

(30) Foreign Application Priority Data
May 11, 2022 (KR) 10-2022-0057741

(51) Int. Cl. H01L 21/687; H01J 37/32; H01L 21/67; H01L 21/683

(52) U.S. Cl. CPC H01L 21/68742; H01L 21/67288; H01J 37/32715; H01J 37/32935; H01L 21/6833; H01L 21/68721

(57) ABSTRACT

The substrate processing device according to an embodiment of the present invention comprises: a control unit for variably controlling the lifting speed of a plurality of lift pins for each of a plurality of lifting sections set on the basis of the lifting heights of the plurality of lift pins that lift a substrate with respect to a support chuck; and a driving unit for driving the plurality of lift pins at a first lifting speed in a first lifting section in which the substrate is lifted, to a set second height, from a first height at which the substrate is placed on the support chuck, and driving the plurality of lift pins at a second lifting speed in at least a part of a second lifting section between the second height and a set third height.

### CROSS-REFERENCE TO RELATED APPLICATIONS

This application claims the benefit under 35 U.S.C. § 120 and § 365 (c) to a prior PCT International Application No. PCT/KR2022/009901, filed on Jul. 8, 2022, which claims the benefit of Korean Patent Application No. 10-2022-0057741, filed on May 11, 2022, the entire contents of which are incorporated herein by reference.

### TECHNICAL FIELD

The present disclosure relates to a substrate processing device and a substrate processing method, and more particularly, to a substrate processing device and a substrate processing method for improving a substrate stickiness phenomenon.

### BACKGROUND ART

A semiconductor integrated circuit is generally a very small and thin silicon chip, but includes various electronic components, and goes through various manufacturing processes including a photo process, an etching process, a deposition process, and a packaging process until a single semiconductor chip is produced. As various materials are deposited on a semiconductor substrate, such as a wafer, a bending deformation (warpage) phenomenon may occur in the semiconductor substrate due to factors, such as different thermal expansion rates. This bending deformation phenomenon appears differently depending on the material of the wafer (e.g., silicon, glass, and the like).

In this way, when plasma processing is performed while a bending deformation occurs in the wafer, local plasma may be generated on a lower surface of the wafer, which may cause a damage to the wafer and components. To prevent this, a clamp load may be applied to the wafer to prevent a bending deformation of the wafer. When using a heavy clamp to completely prevent a bending deformation of the wafer, the wafer is strongly pressed against and closely attached to a support chuck, and accordingly, a stickiness phenomenon may occur between the wafer and the support chuck (e.g., an electrode of an electrostatic chuck).

This stickiness phenomenon is a phenomenon, in which the wafer is stuck to an upper surface of the support chuck, and it becomes a factor that hinders a process of lifting the wafer from the support chuck after the substrate processing process is completed. When the lift pin is driven at a constant speed while the wafer is closely attached to the support chuck due to the stickiness phenomenon, the wafer may suddenly fall off after being stuck to the support chuck, whereby the wafer is shaken so that various problems, such as an unstable wafer lift state and a wafer position deviating from the original position, may be caused.

### DETAILED DESCRIPTION OF THE INVENTION

### Technical Problem

The present disclosure provides a substrate processing device and substrate processing method that improve a substrate stickiness phenomenon by controlling elevation speeds of lift pins that elevate a substrate for elevation sections.

The present disclosure also provides a substrate processing device and a substrate processing method that effectively improve a stickiness phenomenon by controlling elevation speeds of a plurality of lift pins differently.

The present disclosure also provides a substrate processing device and a substrate processing method, by which a stickiness state is predicted depending on a type of a substrate, a process type, and a clamp load, and elevation speeds of lift pins are controlled based on this to effectively improve a stickiness phenomenon.

### Technical Solution

A substrate processing device for processing a substrate according to an embodiment of the present disclosure includes a support chuck that supports the substrate, a plurality of lift pins that elevates the substrate with respect to the support chuck, a driver that drives elevation of the plurality of lift pins, and a controller that controls elevation speeds of the plurality of lift pins by controlling the driver, and the controller differently controls the elevation speeds of the plurality of lift pins for a plurality of elevation sections set with reference to elevation heights of the plurality of lift pins.

The driver may be configured to drive the plurality of lift pins at a first elevation speed in, among the plurality of elevation sections, a first elevation section, in which the substrate is lifted from a first height, at which the substrate is positioned on the support chuck, to a preset second height, and drive the plurality of lift pins at a second elevation speed being higher than the first elevation speed in at least a partial section of a second elevation section, in which the substrate is lifted from the second height to a third height.

The first elevation speed may be set to a speed of a half of the second elevation speed or less to solve a stickiness phenomenon, in which the substrate is stuck to an upper surface of the support chuck while preventing the substrate from being shaken or displaced.

The substrate processing device according to an embodiment of the present disclosure may further include a bending deformation preventing device that applies a load to a circumferential area of the substrate by disposing one or more clamp rings onto the circumferential area of the substrate supported on the support chuck.

The controller may be configured to predict a stickiness state between the substrate and the support chuck depending on a type of the substrate, a process type of processing the substrate, and loads of the clamp rings, which is applied to the circumferential area of the substrate by the clamp rings, and determine the first elevation speed depending on the predicted stickiness state, and control the driver such that the plurality of lift pins are lifted at the first elevation speed in the first elevation section.

The controller may differently control the first elevation speed for the plurality of lift pins in the first elevation section to solve a stickiness phenomenon.

The driver may include a plurality of driving motors that independently drives the plurality of lift pins.

Motor driving speeds of the plurality of driving motors may be differently set in the first elevation section.

The plurality of lift pins may include four or more lift pins arranged along a circumferential direction with respect to a center of the support chuck.

The controller may be configured to control, among the plurality of driving motors, a first driving motor that drives elevation of a first lift pin at a first motor driving speed such that, among the plurality of lift pins, any one first lift pin contacts a lower surface of the substrate first and lifts the substrate in the first elevation section, control a second driving motor that drives elevation of a second lift pin at a second motor driving speed being lower than the first motor driving speed such that, among the plurality of lift pins, the second lift pin being closest to a diagonally opposite side of the first lift pin with respect to the center of the support chuck contacts the lower surface of the substrate next to the first lift pin and lifts the substrate, and control a driving motor that drives elevation of the lift pins at a third motor driving speed being lower than the second motor driving speed such that, among the plurality of lift pins, lift pins other than the first lift pin and the second lift pin contact the lower surface of the substrate next to the second lift pin and lifts the substrate.

The controller may be configured to predict a stickiness state between the substrate and the support chuck depending on a type of the substrate, a process type of processing the substrate, and loads of the clamp rings, which is applied to the circumferential area of the substrate by the clamp rings, and differently control the elevation speeds of the plurality of lift pins in the first elevation section by determining the first motor driving speed, the second motor driving speed, and the third motor driving speed depending on the predicted stickiness state.

A substrate processing method according to an embodiment of the present disclosure includes differently controlling elevation speeds of a plurality of lift pins configured to elevate a substrate with respect to a support chuck, for a plurality of elevation sections set with respect to elevation heights of the plurality of lift pins, by controlling a driver through a controller.

The differently controlling of the elevation speeds of the plurality of lift pins may include driving the plurality of lift pins at a first elevation speed in, among the plurality of elevation sections, a first elevation section, in which the substrate is lifted from a first height, at which the substrate is positioned on the support chuck, to a preset second height, and driving the plurality of lift pins at a second elevation speed being higher than the first elevation speed in at least a partial section of a second elevation section, in which the substrate is lifted from the second height to a third height.

The substrate processing method according to an embodiment of the present disclosure may further include applying a load to a circumferential area of the substrate by disposing one or more clamp rings onto the circumferential area of the substrate supported on the support chuck, by a bending deformation preventing device.

The differently controlling of the elevation speeds of the plurality of lift pins may include predicting a stickiness state between the substrate and the support chuck depending on a type of the substrate, a process type of processing the substrate, and loads of the clamp rings, which is applied to the circumferential area of the substrate by the clamp rings, by the controller, and determining the first elevation speed depending on the predicted stickiness state, and controlling the driver such that the plurality of lift pins are lifted at the first elevation speed in the first elevation section, by the controller.

The differently controlling of the elevation speeds of the plurality of lift pins may include differently controlling the first elevation speed for the plurality of lift pins in the first elevation section to solve the stickiness phenomenon, by the controller.

The differently controlling the first elevation speed for the plurality of lift pins may include independently driving the plurality of lift pins by a plurality of driving motors constituting the driver, and motor driving speeds of the plurality of driving motors are differently set in the first elevation section. Motor driving speeds of the plurality of driving motors may be differently set in the first elevation section.

The independently driving of the plurality of lift pins may include controlling, among the plurality of driving motors, a first driving motor that drives elevation of a first lift pin at a first motor driving speed such that, among the plurality of lift pins, any one first lift pin contacts a lower surface of the substrate first and lifts the substrate in the first elevation section, controlling a second driving motor that drives elevation of the second lift pin at a second motor driving speed being lower than the first motor driving speed such that, among the plurality of lift pins, a second lift pin being closest to a diagonally opposite side of the first lift pin with respect to a center of the support chuck contacts a lower surface of the substrate next to the first lift pin and lifts the substrate, and controlling a driving motor that drives elevation of the lift pins at a third motor driving speed being lower than the second motor driving speed such that, among the plurality of lift pins, lift pins other than the first lift pin and the second lift pin contact the lower surface of the substrate next to the second lift pin and lifts the substrate.

The independently driving of the plurality of lift pins may include predicting a stickiness state between the substrate and the support chuck depending on a type of the substrate, a process type of processing the substrate, and loads of the clamp rings, which is applied to the circumferential area of the substrate by the clamp rings, and differently controlling the elevation speeds of the plurality of lift pins in the first elevation section by determining the first motor driving speed, the second motor driving speed, and the third motor driving speed depending on the predicted stickiness state.

### Advantageous Effects of the Invention

According to the present disclosure, a substrate processing device and substrate processing method that improve a substrate stickiness phenomenon by controlling elevation speeds of lift pins that elevate a substrate are provided.

Furthermore, according to an embodiment of the present disclosure, a substrate processing device and a substrate processing method that effectively improve a stickiness phenomenon by controlling elevation speeds of a plurality of lift pins differently are provided.

Furthermore, according to an embodiment of the present disclosure, a stickiness state is predicted depending on a type of a substrate, a process type, and a clamp load, and elevation speeds of lift pins are controlled based on this to effectively improve a stickiness phenomenon.

### DESCRIPTION OF THE DRAWINGS

FIG. 1 is a cross-sectional view schematically illustrating a substrate processing device according to an embodiment of the present disclosure.

FIGS. 2 and 3 are conceptual views illustrating an operation for improving a stickiness phenomenon of a substrate processing device according to an embodiment of the present disclosure.

FIGS. 4 and 5 are conceptual views illustrating an operation of improving a stickiness phenomenon by individually driving a plurality of lift pins that constitute a substrate processing device according to an embodiment of the present disclosure.

FIG. 6 is a perspective view illustrating a bending deformation preventing device that constitutes a substrate processing device according to an embodiment of the present disclosure.

FIG. 7 is an enlarged perspective view of a portion of part ‘A’ of FIG. 6.

FIG. 8 is a cross-sectional view illustrating an operation state, in which one clamp ring is seated in a circumferential area of a substrate by a substrate processing device according to an embodiment of the present disclosure.

FIG. 9 is an enlarged view of part ‘B’ of FIG. 8.

FIG. 10 is a cross-sectional view illustrating an operation state, in which two clamp rings are seated in a circumferential area of a substrate by a substrate processing device according to an embodiment of the present disclosure.

FIG. 11 is an enlarged view of part ‘C’ of FIG. 10.

FIG. 12 is a flowchart of a substitute processing method according to an embodiment of the present disclosure.

FIG. 13 is a perspective view illustrating a portion of a substrate processing device according to another embodiment of the present disclosure.

FIG. 14 is a cross-sectional view illustrating a part of a substrate processing device according to another embodiment of the present disclosure.

FIGS. 15 and 16 are cross-sectional views illustrating an operation of a substrate processing device according to the embodiment of FIG. 14.

FIG. 17 is a flowchart illustrating a substrate processing method according to an embodiment of the present disclosure.

FIG. 18 is an exemplary view illustrating elevation speed profiles of first and second lift pins that constitute a substrate processing device according to an embodiment of the present disclosure.

### BEST MODE

Hereinafter, embodiments of the present disclosure will be described in more detail with reference to the attached drawings. The embodiments of the present disclosure may be modified in various forms, and the scope of the present disclosure should not be construed as being limited to the embodiments below. The embodiments are provided to more completely explain the present disclosure to an ordinary person in the art. Therefore, the shapes of the elements in the drawings are exaggerated to emphasize a clearer explanation.

The substrate processing device and the substrate processing method, according to an embodiment of the present disclosure is directed to improving a stickiness phenomenon, in which the substrate is stuck to the upper surface of the support chuck in a process of lifting the substrate from the support chuck by the plurality of lift pins after performing processing, such as plasma processing on the substrate positioned on the support chuck, and the elevation speeds of the plurality of lift pins are differently controlled for the plurality of elevation sections that are set with respect to the elevation heights of the plurality of lift pins for the purpose.

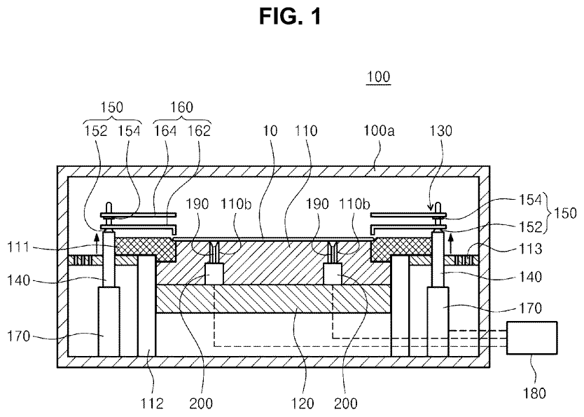

FIG. 1 is a cross-sectional view schematically illustrating a substrate processing device according to an embodiment of the present disclosure. Referring to FIG. 1, a substrate processing device 100 according to an embodiment of the present disclosure is a device that performs a process of processing a substrate 10. The substrate processing device 100 may be various types of devices that perform a process for the substrate 10.

The substrate processing device 100, for example, may be a device that performs a plasma process, a package process, a reflow process, an etching process, a deposition process, a photo process, or a heat treatment process. The substrate 10 that is processed in the substrate processing device 100 according to an embodiment of the present disclosure may be provided as a semiconductor wafer, a mask, a glass substrate, or a liquid crystal display (LCD) panel, but is not limited thereto.

The substrate processing device 100 according to an embodiment of the present disclosure may include a support chuck 110, a processing part 120, a bending deformation preventing device 130, a controller 180, a plurality of lift pins 190, and a driver 200 that are provided in a chamber 100a. The chamber 100a has a processing space, in which the substrate 10 is processed. Various components that are required for processing the substrate 10 may be provided in an interior of the chamber 100a depending on the type of the substrate processing process that is performed by the substrate processing device 100.

For example, when the substrate processing device 100 is provided as a device that processes the substrate 10 by using plasma, a configuration for providing a process gas for generating plasma in the processing space of the chamber 100a, a configuration (for example, a high-frequency generator) for converting a process gas into plasma, and components for exhausting the process gas and the plasma in the processing space may be provided.

The support chuck 110 may be provided to support the substrate 10. The support chuck 110 may be provided as an electrostatic chuck that supports a bottom surface (a lower surface) of the substrate 10, but is not limited thereto. A guide ring 111 for guiding the substrate 10 may be provided around the support chuck 110. The support chuck 110 may be insulated by an insulator 112. Furthermore, an exhaust ring 113 for uniformly discharging the process gas may be provided in the chamber 100a.

The processing part 120 is a configuration for performing the above-described substrate processing process on the substrate 10, and may, for example, include a high-frequency generator for generating and controlling plasma, a high-frequency controller, and a heater for heating the substrate 10.

A plurality of lift pins 190 may be provided in the support chuck 110. As is well known, the lift pin 190 is a device for elevating the substrate 10 and may be configured to lower the substrate 10 carried into the chamber 100a through an entrance/exit 100b by a robot hand (not illustrated) for the substrate processing process and to lift the processed substrate 10 from the support chuck 110.

When the substrate 10 is lifted by the plurality of lift pins 190, the substrate 10 is carried out of the chamber 100a by the robot hand, and then a new substrate for subsequent processing is carried in turn into the chamber 100a by the robot hand to repeatedly perform the substrate processing process.

For an elevation operation of the plurality of lift pins 190, a plurality of elevation grooves 110b may be provided in the support chuck 110. The lift pins 190 may be elevated through the elevation grooves 110b. The lift pins 190 may be lifted and lowered between a height that is lower than an upper surface 110a of the support chuck 110, and a height that is higher than the upper surface 110a of the support chuck 110.

The driver 200 may drive elevation of the plurality of lift pins 190. The driver 200 may include a driving motor for driving elevation of the plurality of lift pins 190, and a driving cylinder, elevation of which is driven by the driving motor. The driver 200 may be implemented to drive the plurality of lift pins 190 in conjunction, or to individually drive the plurality of lift pins 190.

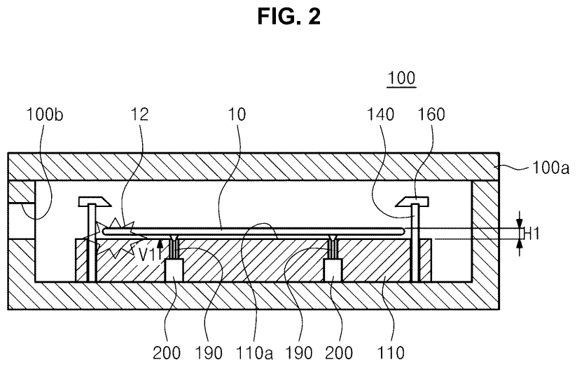

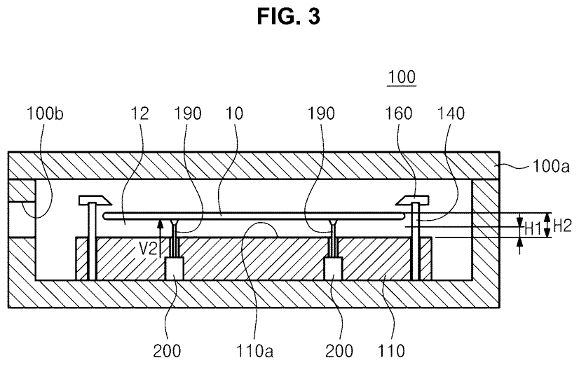

FIGS. 2 and 3 are conceptual views illustrating an operation for improving a stickiness phenomenon of a substrate processing device according to an embodiment of the present disclosure. Referring to FIGS. 1 to 3, to improve the stickiness phenomenon 12, in which the substrate is stuck to the upper surface 110a of the support chuck 110, the driver 200 may be controlled by the controller 180 to drive the plurality of lift pins 190 at different elevation speeds for the plurality of elevation sections that are set with reference to the elevation heights of the plurality of lift pins 190.

To this end, the controller 180 controls the driver 200 for each of the plurality of elevation sections including a first elevation section and a second elevation section to differently control the elevation speeds of the plurality of lift pins 190. As illustrated in FIG. 2, the first elevation section may be a section, in which the substrate 10 is lifted from a first height (e.g., a height of the upper surface of the support chuck) positioned on the support chuck 110 to a second height H1 (e.g., a height that is several mm to several cm higher than the upper surface of the support chuck).

The second elevation section is a section that is higher than the first elevation section, and as illustrated in FIG. 3, may be a section, in which the substrate 10 is lifted from the second height H1 to a third height H2 (e.g., a height that is several cm to several tens of cm higher than the upper surface of the support chuck). The third height H2 may, for example, be a height, at which the substrate 10 is carried out to an outside of the chamber 100a by a robot hand.

As illustrated in FIG. 2, the driver 200 may drive the plurality of lift pins 190 at a first elevation speed V1 in the first elevation section, and may drive the plurality of lift pins 190 at a second elevation speed V2 that is higher than the first elevation speed V1 that is an elevation speed in the first elevation section, in the second elevation section or in some sections of the second elevation section, as illustrated in FIG. 3.

In an embodiment of the present disclosure, the first elevation speed V1 of the lift pin 190 in the first elevation section may be set to a speed that is a half of the second elevation speed V2 of the lift pin 190 or lower in the second elevation section to effectively solve the stickiness phenomenon, in which the substrate 10 is stuck to the upper surface 110a of the support chuck 110 while preventing the shaking or displacement of the substrate 10.

For example, the first elevation speed V1 of the lift pin 190 in the first elevation section may be set to a speed of 5% to 30% of the second elevation speed V2 of the lift pin 190 in the second elevation section. Alternatively, the first elevation speed V1 of the lift pin 190 in the first elevation section may be set to a speed of 50% of the overall average elevation speed of the lift pin 190 or less.

Accordingly, it is possible to improve the stickiness phenomenon 12 between the substrate 10 and the support chuck 110 by stably separating the substrate 10 from the upper surface 110a of the support chuck 110 while the substrate 10 not being shaken or displaced as the plurality of lift pins 190 are lifted in the first elevation section at an elevation speed that is lower than the elevation speed in the second elevation section.

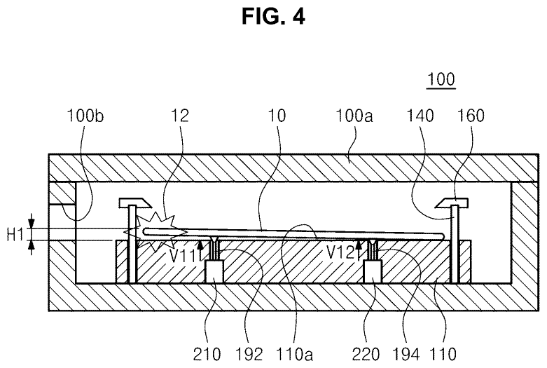

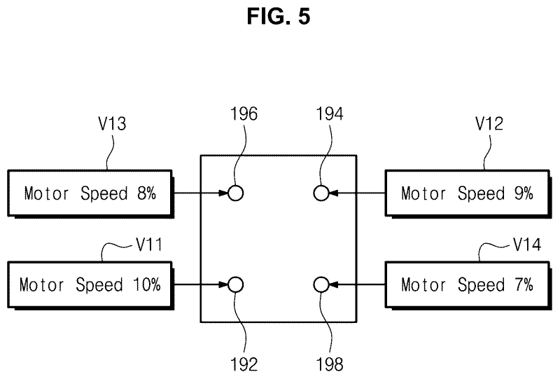

FIGS. 4 and 5 are conceptual views illustrating an operation of improving a stickiness phenomenon by individually driving a plurality of lift pins that constitute a substrate processing device according to an embodiment of the present disclosure. FIG. 4 illustrates individual driving states of the plurality of lift pins 190 in the first elevation section illustrated in FIG. 2. FIG. 5 is an exemplary view illustrating the elevation speeds of the plurality of lift pins.

Referring to FIGS. 1 to 5, the plurality of lift pins 190 may include four or more lift pins 192, 194, 196, and 198 that are arranged along a circumferential direction with respect to a center of the support chuck 110. The driver 200 may include a plurality of drive motors that independently drive the plurality of lift pins 190. The controller 180 may differently control the first elevation speed V1 for each of a plurality of lift pins 190 in the first elevation section to solve the stickiness phenomenon.

In the embodiment, the motor driving speeds of the plurality of driving motors that constitute the driver 200 may be set differently in the first elevation section. In the example illustrated in FIG. 5, the motor driving speeds V11, V12, V12, V13, and V14 of the first to fourth driving motors of the driver 200 that drives the first to fourth lift pins 192, 194, 196, and 198 are set to 10%, 9%, 8%, and 7% of the motor driving speed (100%) in the second elevation section, respectively.

More specifically, the controller 180 may control, among the plurality of driving motors of the driver 200, a first driving motor 210 that drives elevation of the first lift pin 192 to the first motor driving speed V11 so that, among the plurality of lift pins 190, the first lift pin 192 contacts a lower surface of the substrate 10 first in the first elevation section and lifts the substrate 10.

The controller 180 may control a second driving motor 220 that drives elevation of the second lift pin 194 to the second motor driving speed V12 that is lower than the first motor driving speed V11 so that, among the plurality of lift pins 190, the second lift pin 194 that is closest to an diagonally opposite side of the first lift pin 192 contacts the lower surface of the substrate 10 next to the first lift pin 192 with respect to the center of the support chuck 110 and lifts the substrate 10.

Furthermore, the controller 180 may control the driving motors that drives elevation of the third and fourth lift pins 196 and 198 to the third and fourth motor driving speeds V13 and V14 that are lower than the second motor driving speed V12 so that, among the plurality of lift pins 190, the lift pins 196 and 198 except for the first lift pin 192 and the second lift pin 194 contact the lower surface of the substrate 10 next to the second lift pin 194 and lift the substrate 10.

Accordingly, the first to fourth lift pins 192, 194, 196, and 198 sequentially contact the lower surface of the substrate 10 at a time interval and lift the substrate 10 so that the substrate 10 may be stably lifted from the support chuck 110 without a risk of being shaken or displaced by improving the stickiness phenomenon.

Furthermore, the stickiness phenomenon may be improved while instability caused due to the inclination of the substrate 10 may be minimized by lifting the substrate 10 initially by the first lift pin 192 and subsequently lifting the substrate 10 by the second lift pin 194 located on a diagonal side of the first lift pin 192 rather than sequentially lifting the plurality of lift pins 192, 194, 196, and 198 in a clockwise or counterclockwise order.

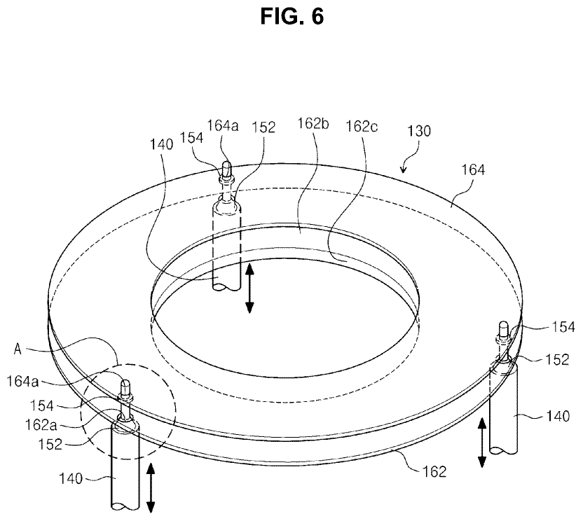

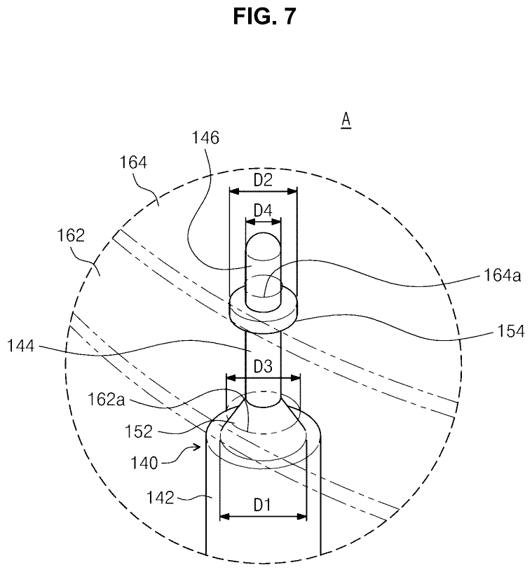

FIG. 6 is a perspective view illustrating a bending deformation preventing device that constitutes a substrate processing device according to an embodiment of the present disclosure. FIG. 7 is an enlarged perspective view of a portion of part ‘A’ of FIG. 6. Referring to FIGS. 1 to 7, the bending deformation preventing device 130 may be configured to prevent a bending deformation (warpage) of the substrate 10 by disposing one or more clamp rings 162 and 164 onto a circumferential area (for example, a peripheral part of the substrate) of the substrate 10 that is supported on the support chuck 110 to apply a load to the circumferential area of the substrate 10.

Because the bending deformation of the substrate 10 mainly occurs in the circumferential area (peripheral area) of the substrate 10 during the substrate processing process, the clamp rings 162 and 164 may be provided in a ring shape to press the circumferential area of the substrate 10. In the illustrated example, the clamp rings 162 and 164 are formed of a disk having a circular ring shape, but may be modified into a rectangular ring or the like depending on the shape of the substrate 10.

The bending deformation preventing device 130 may include a plurality of pins 140, a plurality of support members 150, a plurality of clamp rings 160, and an elevation driver 170. The plurality of pins 140 may be disposed along a circumference of the support chuck 110. In other words, the plurality of pins 140 may be arranged to surround the support chuck 110, and the substrate 10 that is supported on the support chuck 110.

In the illustrated example, three pins 140 are arranged at an interval of 120° around the support chuck 110, but the number and arrangement interval of the pins 140 may be variously modified. The plurality of pins 140 may extend in an upward/downward direction so that the plurality of clamp rings 160 may be elevated. The plurality of pins 140 may be elevated by the elevation driver 170.

The plurality of clamp rings 160 may include a first clamp ring 162 and a second clamp ring 164. The clamp rings 162 and 164 may be provided to have a weight, by which a bending deformation of the substrate 10 may be prevented. The clamp rings 162 and 164 may be provided to be positioned on a peripheral area of the substrate 10 that is positioned on the support chuck 110.

The first clamp ring 162 may include a ring-shaped disk 162b, and a load applying plate 162c that is formed in a box shape, such as a cylindrical or rectangular box shape, which extends from an inner diameter part of the disk 162b to apply a load to the circumferential area of the substrate 10. The load applying plate 162c may be provided in the same shape as that of the circumferential area of the substrate 10.

In an embodiment, when the substrate 10 has a disk shape, the clamp rings 162 and 164 may be provided as a circular ring-shaped plate, a central portion of which is opened. The clamp rings 162 and 164 may be designed such that an inner diameter part thereof is close to an outer diameter part of the substrate 10, and may be formed to extend radially outward from the inner diameter part.

The plurality of clamp rings 162 and 164 may be disposed to be concentric to the center of the support chuck 110 and the center of the substrate 10 supported on the support chuck 110. Furthermore, the plurality of clamp rings 162 and 164 may be disposed to be spaced apart from each other in the upward/downward direction by a plurality of support members 150 provided in the plurality of pins 140.

Each of the pins 140 may include a first pin member 142, a second pin member 144 having a smaller diameter than that of the first pin member 142, and a third pin member 146 having a smaller diameter than that of the second pin member 144. The plurality of support members 150 may be provided in a plurality of pins 140 along the upward/downward direction to support the clamp rings 162 and 164 in a horizontal direction.

The plurality of support members 150 may include a first support member 152 and a second support member 154. The first support member 152 may be formed between the first pin member 142 and the second pin member 144. The second support member 154 may be formed between the second pin member 144 and the third pin member 146.

The first support member 152 may be provided at a first position (a lower position) of the plurality of pins 140, and the second support member 154 may be provided at a second position (an upper position) that is higher than the first position of the plurality of pins. The first support member 152 and the second support member 154 may protrude from circumferential portions of the pins 140 to support bottom surfaces of the plurality of clamp rings 162 and 164, respectively.

The plurality of clamp rings 162 and 164 may be supported on the plurality of support members 152 and 154 while being positioned thereon. The first clamp ring 162 may be supported on the plurality of first support members 152 formed on the plurality of pins 140. To support the first clamp ring 162 in parallel to the substrate 10, the plurality of first support members 152 may be formed in the plurality of pins 140 at the same height.

The second clamp ring 164 may be supported on the plurality of second support members 154 formed on the plurality of pins 140. To support the second clamp ring 164 in parallel to the substrate 10, the plurality of second support members 154 may be formed in the plurality of pins 140 at the same height. In this way, the plurality of clamp rings 162 and 164 including the first clamp ring 162 and the second clamp ring 164 may be supported while being spaced apart by the plurality of support members 152 and 154 formed on the plurality of pins 140 in the upward/downward direction.

The plurality of clamp rings 162 and 164 may be formed with through-holes 162a and 164a, through which the plurality of pins 140 pass. The first clamp ring 162 may include a plurality of first through-holes 162a, through which a plurality of pins 140 pass. The second clamp ring 164 may include a plurality of second through-holes 164a, through which a plurality of pins 140 pass. The plurality of first through-holes 162a and the plurality of second through-holes 164a may be formed at positions corresponding to the first clamp ring 162 and the second clamp ring 164 in the upward/downward direction.

The first through-holes 162a of the first clamp ring 162 and the second through-holes 164a of the second clamp ring 164 may have different sizes or different shapes. The first through-holes 162a may have shapes, through which a plurality of first support members 152 cannot pass, so that the first clamp ring 162 may be supported by the first support member 152.

Furthermore, the first through-holes 162a may have a shape, through which the plurality of second support members 154 may pass. In other words, the second support member 154 may be provided in a shape, through which the first through-hole 162a may pass. The second through-holes 164a may have a shape, through which the plurality of second support members 154 may not pass, so that the second clamp ring 164 may be supported by the second support member 154.

The elevation driver 170 may be driven by the controller 180 to drive elevation of the plurality of pins 140. The elevation driver 170 may, for example, be implemented as a hydraulic cylinder, a hydraulic motor, a screw shaft/guide bar, or the like for driving elevation of the plurality of pins 140, but is not limited thereto, and various driving methods capable of driving elevation of the plurality of pins 140 may be used.

The elevation driver 170 may be configured to drive elevation of the plurality of pins 140 by a specific spacing distance or more between the first clamp ring 162 and the second clamp ring 164. In an embodiment, the elevation driver 170 may be provided to pass through the exhaust ring 113 on an outside of the guide ring 111.

The controller 180 may drive elevation of the plurality of pins 140 by controlling the elevation driver 170 so that the number of the clamp rings 162 and 164 positioned on the circumferential part (peripheral part) of the substrate 10 is adjusted depending on the elevation heights of the plurality of pins 140.

The controller 180 may adjust the clamp load applied to the substrate 10 by selecting any one of a first mode, in which the first clamp ring 162 is positioned in the circumferential area of the substrate 10 by controlling the elevation driver 170 to lower the plurality of pins 140 by a height of the first pin, and a second mode, in which the first clamp ring 162 and the second clamp ring 164 are positioned in the circumferential area of the substrate 10 by controlling the elevation driver 170 to lower the plurality of pins 140 by a height of the second pin.

In an embodiment, the first support member 152 may be provided in a truncated conical shape of a narrow upper side and a wide lower side. The first through-hole 162a formed in the first clamp ring 162 may not pass through the first support member 152 while a pin 140 passes therethrough, and may be formed to have a first diameter D3 so that the second support member 154 may pass therethrough. The lower diameter D1 of the first support member 152 may be formed to be greater than the first diameter D3 of the first through-hole 162a, and the upper diameter of the first support member 152 may be formed to be equal to or smaller than the first diameter D3 of the first through-hole 162a.

The second support member 154 may be formed in an upper area of the pin 140, and may be provided in a circular ring shape that surrounding the upper area of the pin 140. A second through-hole 164a may have a second diameter D4 that is smaller than the first diameter D3 of the first through-hole 162a so that the second support member 154 may not pass therethrough while the pin 140 passes therethrough. The second diameter D4 of the second through-hole 164a may be smaller than the diameter D2 of the second support member 154, and may be formed to be equal to or slightly greater than the diameter of the upper area of the pin 140.

The diameter D2 of the second support member 154 may be greater than the second diameter D4 of the second through-hole 164a, and may be equal to or smaller than the first diameter D3 of the first through-hole 162a. When the pin 140 is lowered by the evaporation driver 170, the second support member 154 may be lowered by passing through the first through-hole 162a of the first clamp ring 162, and accordingly, the second support member 154 may be spaced apart downward from a bottom surface of the second clamp ring 164 so that the second clamp ring 164 may be positioned on the first clamp ring 162.

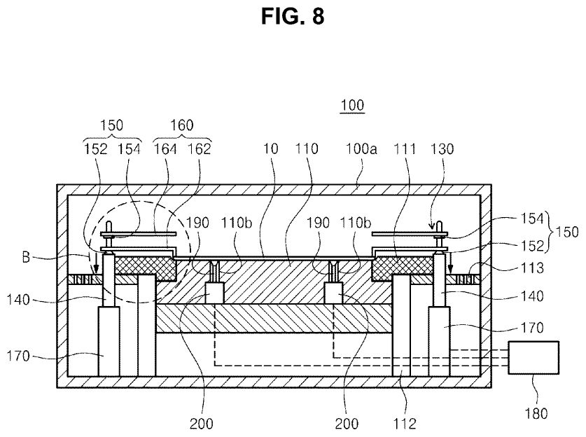

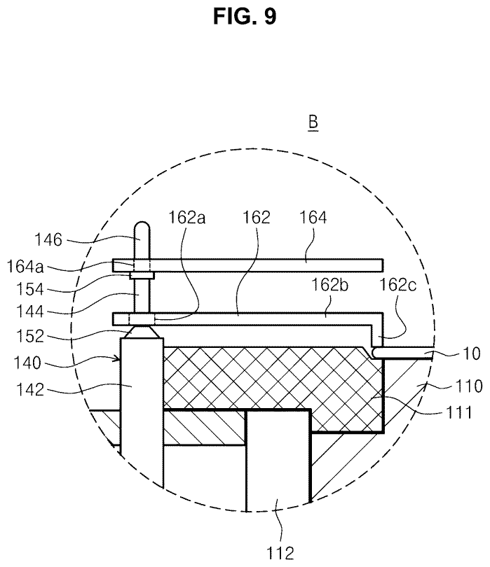

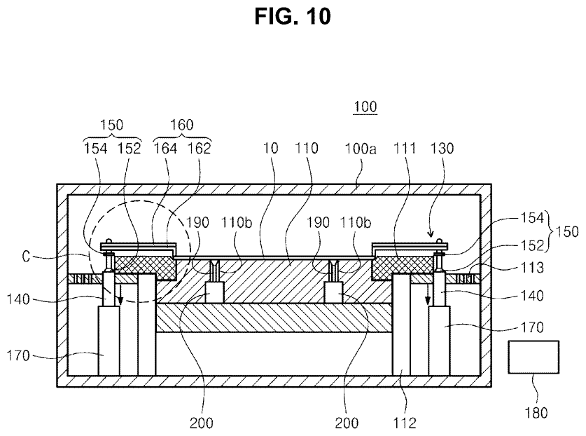

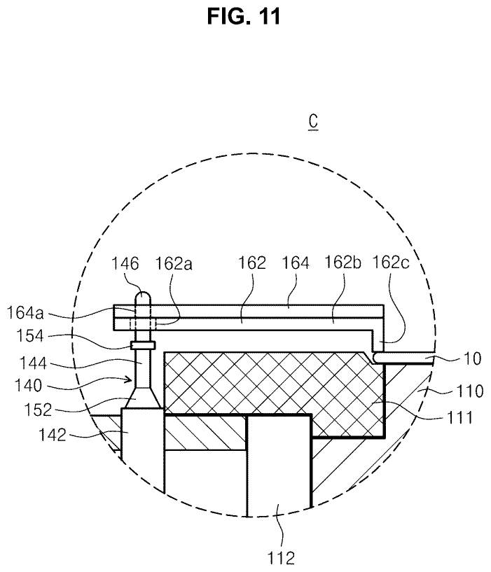

FIG. 8 is a cross-sectional view illustrating an operation state, in which one clamp ring is seated in a circumferential area of a substrate by a substrate processing device according to an embodiment of the present disclosure. FIG. 9 is an enlarged view of part ‘B’ of FIG. 8. FIG. 10 is a cross-sectional view illustrating an operation state, in which two clamp rings are seated in a circumferential area of a substrate by a substrate processing device according to an embodiment of the present disclosure. FIG. 11 is an enlarged view of part ‘C’ of FIG. 10.

Referring to FIGS. 1 to 11, the controller 180 may determine the elevation heights of a plurality of pins 140 depending on at least one of the material of the substrate 10 and the substrate processing process, and may adjust the number of the clamp rings 162 and 164 positioned in the circumferential area of the substrate 10 by elevating the plurality of pins 140 depending on the determined elevation height.

As the plurality of pins 140 are lowered by the controller 180 and the elevation driver 170, the number of the clamp rings 162 and 164 positioned on the circumferential area of the substrate 10 may be increased step by step. Conversely, when the plurality of pins 140 are lifted by the controller 180 and the elevation driver 170, the number of the clamp rings 162 and 164 positioned in the circumferential area of the substrate 10 may be decreased step by step. In the illustrated example, two clamp rings 162 and 164 are used, but three or more clamp rings may be used.

According to an embodiment of the present disclosure, a bending deformation (warpage) may be controlled for various materials of the substrate and various substrate processing processes by selectively using the number of the clamp rings positioned in the circumferential area of the substrate depending on the material of the substrate or the substrate processing process by using the plurality of clamp rings.

For example, in the case of a substrate made of a brittle material, a bending deformation of the substrate 10 may be prevented without a breakage with a small load of one clamp ring 162 by applying a load to the circumferential area of the substrate 10 with, among the plurality of clamp rings 162 and 164, one clamp ring 162 located on a lower side to perform the substrate processing process.

Unlike this, when a rigidity of the substrate is strong, the bending deformation of the substrate 10 may be effectively controlled with a higher load by lowering the plurality of pins 140 to applying a load to the circumferential area of the substrate 10 with two clamp rings 162 and 164 or three or more clamp rings to perform the substrate processing process.

In this way, by adjusting and using the number of the clamp rings 162 and 164 positioned in the circumferential area of the substrate 10 depending on the material of the substrate 10 or the substrate processing process, problems, such as a local plasma damage due to the bending deformation during processing of the substrate, for example, by using plasma while the stress received by the substrate 10 is minimized.

In the illustrated example, three pins 140 are formed around the support chuck 110, but the number of the pins 140 may be changed to four or more. Also, in the illustrated example, the clamp ring 160 has a circular ring shape, but may be modified into a rectangular ring shape or the like depending on the shape of the substrate.

When the processing of the substrate 10 is completed, after the plurality of pins 140 are returned to an upper position by the controller 180 and the elevation driver 170 to space the clamp rings 162 and 164 apart from the upper surface of the substrate 10, the substrate 10 may be carried out of the chamber 100a by a substrate transfer device (not illustrated), and a substrate 10 that is to be processed may be carried into the chamber 100a and may be supported on the support chuck 110.

The controller 180 determines the appropriate number of clamp rings 162 and 164 according to the type of the substrate 10 supported on the support chuck 110 or a substrate processing process that is to be performed on the substrate 10, and thus, the elevation driver 170 is operated to lower the plurality of pins 140 to perform a subsequent substrate processing process while an appropriate number of clamp rings 162 and 164 are positioned on the circumferential area of the substrate 10.

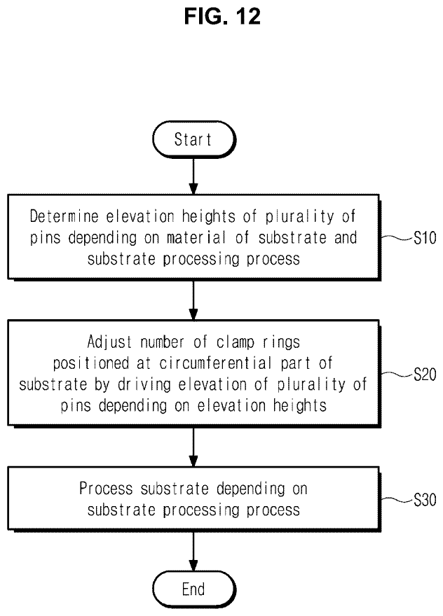

FIG. 12 is a flowchart of a substitute processing method according to an embodiment of the present disclosure. Referring to FIGS. 1 and 12, the elevation heights of the plurality of pins 140 may be determined depending on the material of the substrate 10, on which a substrate processing process is to be performed by the substrate processing device 100 and/or a substrate processing process (S10).

The controller 180 may adjust the number of the clamp rings 162 and 164 positioned in the circumferential area of the substrate 10 by driving elevation of the plurality of pins 140 depending on the elevation heights of the plurality of pins 140 to elevate the plurality of clamp rings 162 and 164 supported by the plurality of support members 152 and 154 (S20). When an appropriate number of clamp rings 162 and 164 are positioned in the circumferential area of the substrate 10, a substrate processing process may be performed on the substrate 10 (S30).

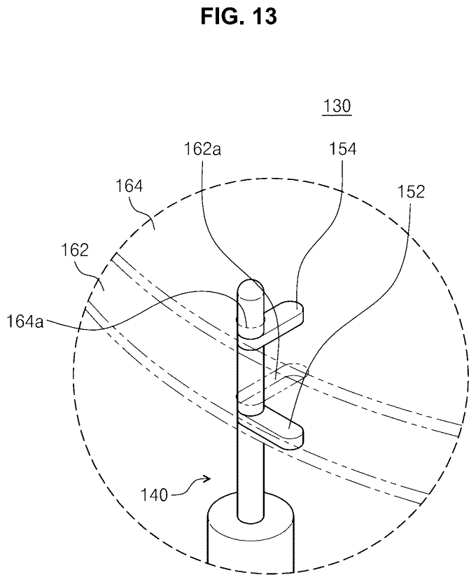

FIG. 13 is a perspective view illustrating a portion of a substrate processing device according to another embodiment of the present disclosure. The substrate processing device according to the embodiment of FIG. 13 differs from the aforementioned embodiment in that the first support member 152 and the second support member 154 that constitute the bending deformation preventing device 130 are coupled to the pins 140 in different directions, and the first through-hole 162a formed in the first clamp ring 162 has a slot shape corresponding to the second support member 154.

The plurality of pins 140 may be formed to pass through end areas of the plurality of first through-holes 162a. When the pin 140 is lowered, the bar-shaped second support member 154 may be lowered while passing through the slot-shaped first through-hole 162a of the first clamp ring 162, and accordingly, the second support member 154 may be spaced apart from the lower surface of the second clamp ring 164 so that the second clamp ring 164 may be positioned on the first clamp ring 162.

When the pin 140 is lifted, the bar-shaped second support member 154 is lifted while passing through the slot-shaped first through-hole 162a of the first clamp ring 162, and contacts the lower surface of the second clamp ring 164 to lift the second clamp ring 164, and accordingly, the second clamp ring 164 is moved to an upper position.

Furthermore, when the pin 140 continues to be lifted, the bar-shaped first support member 152 contacts the lower surface of the first clamp ring 162 and lifts the first clamp ring 162, and accordingly, the first clamp ring 162 positioned on the circumferential area of the substrate 10 is moved to an upper position.

According to the embodiment of FIG. 13, the plurality of pins 140 are formed to pass through the end areas of the plurality of first through-holes 162a, respectively, so that a central position of the first clamp ring 162 may be prevented from being twisted in a radial direction during the elevation operation of the plurality of pins 140. The central position of the second clamp ring 164 is also not twisted in the radial direction by the plurality of pins 140 that pass through the plurality of second through-holes 164a.

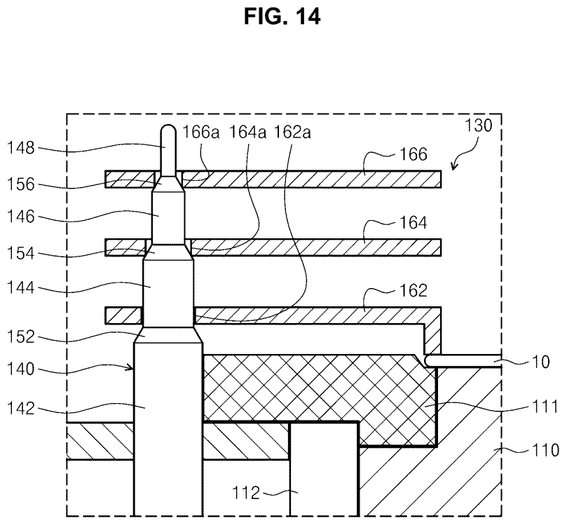

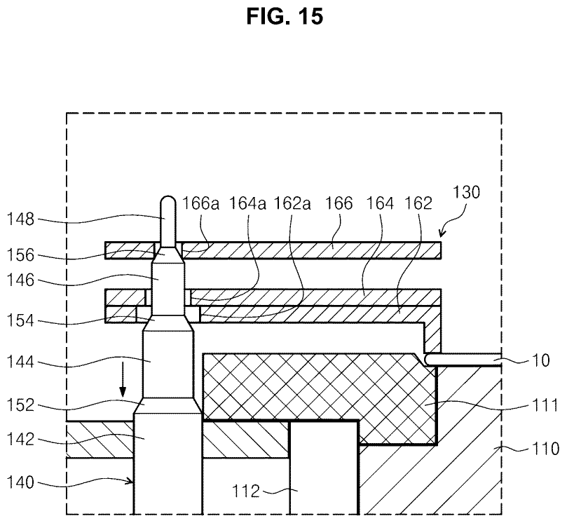

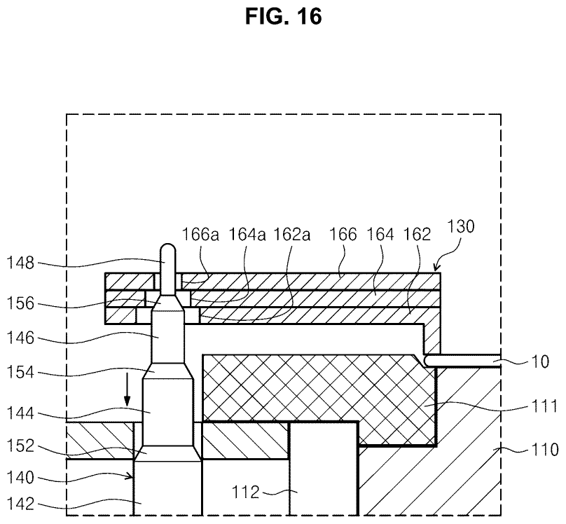

FIG. 14 is a cross-sectional view illustrating a part of a substrate processing device according to another embodiment of the present disclosure. FIGS. 15 and 16 are cross-sectional views illustrating an operation of a substrate processing device according to the embodiment of FIG. 14. The substrate processing device according to the embodiment of FIGS. 14 to 16 differs from the aforementioned embodiment in that the bending deformation preventing device 130 includes three support members 152, 154, and 156 and three clamp rings 162, 164, and 166. Each of the pins 140 may include pin members 142, 144, 146, and 148, of which diameters decreases toward an upper portion step by step.

Each of the support members 152, 154, and 156 may be provided in a truncated conical shape, of which a diameter decreases toward an upper side. An average diameter of, among the support members 152, 154, and 156, the first support member 152 is the largest, an average diameter of the second support member 154 may be smaller than that of the first support member 152, and an average diameter of the third support member 156 may be smaller than that of the second support member 156.

Among the support members 152, 154, and 156, the first support member 152 has the largest average diameter, the average diameter of the second support member 154 may be smaller than the average diameter of the first support member 152, and the average diameter of the third support member 156 may be smaller than the average diameter of the second support member 156.

The first support member 152 may be provided between the first pin member 142 and the second pin member 144. The second support member 154 may be provided between the second pin member 144 and the third pin member 146. The third support member 156 may be provided between the third pin member 146 and the fourth pin member 148.

The first through-hole 162a of the first clamp ring 162 may be formed to have a diameter that is smaller than a maximum diameter (a lower diameter) of the first support member 152, and is greater than a minimum diameter (an upper diameter). The second through-hole 164a of the second clamp ring 164 may be formed to have a diameter that is smaller than a maximum diameter (a lower diameter) of the second support member 154, and is greater than a minimum diameter (an upper diameter).

The third through-hole 166a of the third clamp ring 166 may be formed to have a diameter that is smaller than a maximum diameter (a lower diameter) of the third support member 156, and is greater than a minimum diameter (an upper diameter). Accordingly, the first clamp ring 162 may be supported by the first support member 152. Similarly, the second clamp ring 164 may be supported by the second support member 154, and the third clamp ring 166 may be supported by the third support member 156.

In FIG. 14, only a load of the first clamp ring 162 is applied to the circumferential area of the substrate 10 while the plurality of pins 140 are lowered by a first height. When the pin 140 is further lowered by a second height, not only a load of the first clamp ring 162 but also a load of the second clamp ring 164 are applied to the circumferential area of the substrate 10, so that a higher clamp load is applied to the substrate 10.

Furthermore, when a number of pins 140 are further lowered by a third height, a load of the third clamp ring 166, as well as the loads of the first clamp ring 162 and the second clamp ring 164, is also applied to the circumferential area of the substrate 10 so that the clamp load applied to the circumferential area of the substrate 10 is further increased.

Conversely, when a plurality of pins 140 are lifted, the third support member 156 first contacts a bottom surface of the third clamp ring 166 to lift the third clamp ring 166. Subsequently, when the plurality of pins 140 are further lifted, the second support member 154 contacts a bottom surface of the second clamp ring 164 to lift the second clamp ring 164.

Thereafter, when the plurality of pins 140 are further lifted, the first support member 152 contacts a bottom surface of the first clamp ring 162 to lift the first clamp ring 162. In this way, when all the clamp rings 162, 164, and 166 positioned on the circumferential area of the substrate 10 are moved upward, the substrate 10 may be carried out.

According to the substrate processing device of FIGS. 14 to 16, depending on the substrate 10 and/or substrate processing process, one clamp ring, two clamp rings, or three clamp rings may be selectively positioned in the circumferential area of the substrate 10 to variously adjust the clamp load applied to the circumferential area of the substrate 10 in three load modes.

Furthermore, although not illustrated, it is also possible to adjust the clamp load applied to the circumferential area of the substrate 10 to four or more load modes by using four or more clamp rings. Furthermore, by applying various weights of clamp rings, the clamp load applied to the substrate 10 may be variously changed by adjusting the elevation heights of a plurality of pins 140.

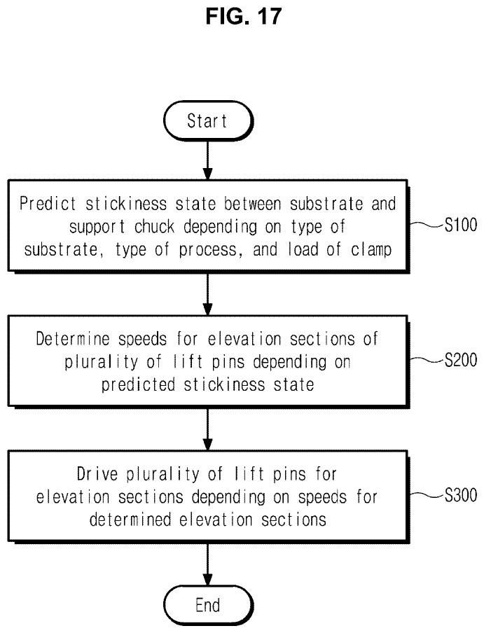

FIG. 17 is a flowchart illustrating a substrate processing method according to an embodiment of the present disclosure. Referring to FIGS. 1 to 5 and 17, the controller 180 may predict a stickiness state between the substrate 10 and the support chuck 110 depending on the type of substrate 10, the type of a process performed on the substrate 10, and the clamp ring load applied to the circumferential area of the substrate 10 by one or more clamp rings (S100).

In an embodiment, the controller 180 may predict the stickiness state based on a relationship or a relationship table that represents the type of the substrate, the process type, and the clamp ring load, or a regression model obtained through a regression analysis or an artificial intelligence learned based on learning data.

The substrate type may include a classification of the type of the substrate, such as a semiconductor wafer, a mask, a glass substrate or a liquid crystal display panel, the material of the substrate, the size of the substrate, the thickness of the substrate, a rigidity/strength of the substrate, and the like. The process type may include a classification of process types, such as plasma process, package process, reflow process, etching process, deposition process, photo process, heat treatment process, a process recipe, such as the type of a process gas, a process temperature, a process pressure, a process time, and the like.

For example, the clamp ring load may include information, such as the number of clamp rings that press the peripheral part of the substrate during the substrate processing process, the size of the clamp rings, the weight of the clamp rings, a pressure that presses the clamp ring when the substrate is clamped by pressing the clamp rings, and a contact form between the clamp rings and the substrate.

As the load of the clamp ring becomes higher, the stickiness phenomenon between the substrate and the support chuck may become severer, and a difference between the first elevation speed and the second elevation speed and/or a difference between the first elevation speeds between the plurality of lift pins may increase in proportion to the load of the clamp rings, and in the opposite case, a difference between the first elevation speed and the second elevation speed and/or a difference between the first elevation speed between a plurality of lift pins may be reduced.

When the stickiness state between the substrate 10 and the support chuck 110 is predicted, the controller 180 may determine a first elevation speed V1 for individually elevating the plurality of lift pins 190 in the first elevation section and a second elevation speed V2 for elevating the plurality of lift pins 190 in the second elevation section to improve the stickiness state depending on the predicted stickiness state (S200).

When the first elevation speed V1 and the second elevation speed V2 are determined for each of a plurality of lift pins 190, the controller 180 may independently drive the plurality of lift pins 190 for the elevation sections by controlling the driver 200 depending on the elevation speeds determined for each of the lift pins 190, for elevation sections (S300).

Specifically, the controller 180 may determine the motor driving speeds of the plurality of driving motors that constitute the driver 200 that drives the plurality of lift pins 190 depending on the predicted stickiness state, and may control the elevation speeds V1 and V2 differently for each of the plurality of lift pins 190 in the first elevation section.

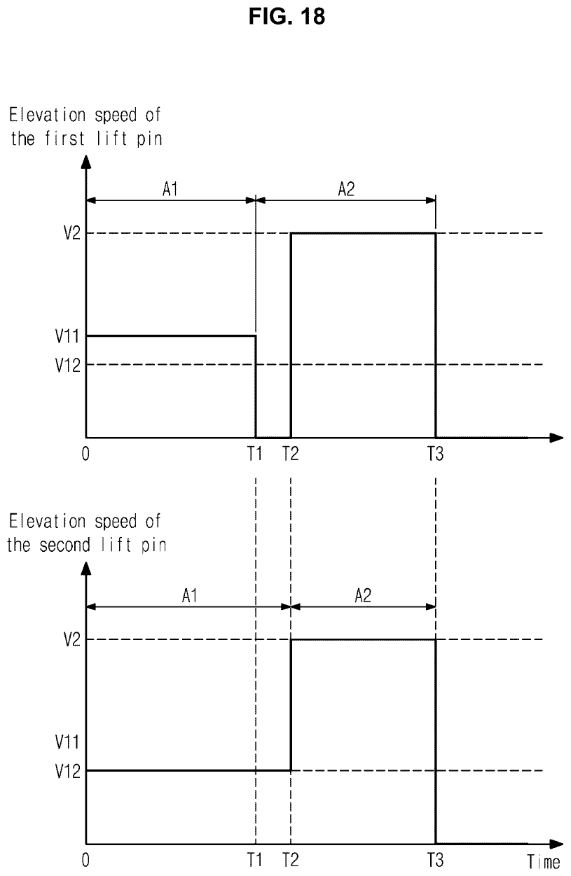

FIG. 18 is an exemplary view illustrating elevation speed profiles of first and second lift pins that constitute a substrate processing device according to an embodiment of the present disclosure. The upper graph of FIG. 18 illustrates an elevation speed profile of the first lift pin that lifts the substrate first in the first elevation section, and a lower graph of FIG. 18 illustrates an elevation speed profile of the second lift pin that lifts the substrate after the first lift pin.

After the substrate processing process is completed, a lift operation of lifting the substrate from the support chuck is started. In the first elevation section A1 of a section of time 0 to T1, the first elevation speeds V1 of the first and second lift pins are set to be lower than the second elevation speed V2, which is a maximum elevation speed of the second elevation section A2.

Furthermore, the first lift pin is lifted at the first elevation speed V1, and the second lift pin is lifted at the second elevation speed V2 that is lower than the first elevation speed V1. Accordingly, the first lift pin first lifts one side of the lower surface of the substrate at a decreased elevation speed to solve the stickiness phenomenon.

The first lift pin reaches a height of an upper end of the first elevation section at the first time T1. The second lift pin is lifted at a lower speed than that of the first lift pin and reaches a height of an upper end of the first elevation section at the second time T2 after the first time T1. The first lift pin reaches the height of the upper end of the first elevation section at the first time T1, and then waits until another lift pin reaches the corresponding height.

Thereafter, in the second elevation section from the second time T2 to the third time T3, the first lift pin and the second lift pin are lifted to the second elevation speed V2 that is increased from the first elevation speed V1 in the first elevation section, and reach the height of the upper end of the second elevation section at the third time T3.

When the lift pin that lifts the substrate reaches the height of the upper end of the second elevation section, the substrate is handed over by the robot hand that entered the chamber, and the lift pin is handed over by the robot hand, and the lift pin is lowered and the substrate is carried out of the chamber together with the robot hand. Thereafter, a new substrate is carried into the chamber by the robot hand, and a subsequent process is started.

The above detailed description is illustrative of the present disclosure. In addition, the above contents are described by showing a preferred embodiment of the present disclosure, and the present disclosure may be used in various other combinations, modifications, and environments. That is, changes or modifications are possible within the scope of the concept of the present disclosure disclosed in this specification, the scope equivalent to the written disclosure, and/or the scope of technology or knowledge in the art.

The written embodiment describes the best state for implementing the technical idea of the present disclosure, and various changes required for specific application fields and uses of the present disclosure are also possible. Therefore, the above detailed description of the disclosure is not intended to limit the present disclosure to the disclosed embodiments. In addition, the appended claims should be interpreted to include other embodiments.

1. A substrate processing device for processing a substrate, comprising:
a support chuck configured to support the substrate;
a plurality of lift pins configured to elevate the substrate with respect to the support chuck;
a driver configured to drive elevation of the plurality of lift pins; and
a controller configured to control elevation speeds of the plurality of lift pins by controlling the driver,
wherein the controller differently controls the elevation speeds of the plurality of lift pins for a plurality of elevation sections set with reference to elevation heights of the plurality of lift pins, and
wherein the driver is configured to:
drive the plurality of lift pins at a first elevation speed in, among the plurality of elevation sections, a first elevation section, in which the substrate is lifted from a first height, at which the substrate is positioned on the support chuck, to a preset second height; and
drive the plurality of lift pins at a second elevation speed being higher than the first elevation speed in at least a partial section of a second elevation section, in which the substrate is lifted from the second height to a third height.

2. The substrate processing device of claim 1, wherein the first elevation speed is set to a speed of a half of the second elevation speed or less to solve a stickiness phenomenon, in which the substrate is stuck to an upper surface of the support chuck.

3. The substrate processing device of claim 1, further comprising:
a bending deformation preventing device configured to apply a load to a circumferential area of the substrate by disposing one or more clamp rings onto the circumferential area of the substrate supported on the support chuck,
wherein the controller is configured to:
predict a stickiness state between the substrate and the support chuck depending on a type of the substrate, a process type of processing the substrate, and loads of the clamp rings, which is applied to the circumferential area of the substrate by the clamp rings; and
determine the first elevation speed depending on the predicted stickiness state, and control the driver such that the plurality of lift pins are lifted at the first elevation speed in the first elevation section.

4. The substrate processing device of claim 1, wherein the controller differently controls the first elevation speed for the plurality of lift pins in the first elevation section to solve a stickiness phenomenon, in which the substrate is stuck to an upper surface of the support chuck.

5. The substrate processing device of claim 4, wherein the driver includes a plurality of driving motors configured to independently drive the plurality of lift pins, and
wherein motor driving speeds of the plurality of driving motors are differently set in the first elevation section.

6. The substrate processing device of claim 5, wherein the plurality of lift pins include four or more lift pins arranged along a circumferential direction with respect to a center of the support chuck, and
wherein the controller is configured to:
control, among the plurality of driving motors, a first driving motor configured to drive elevation of a first lift pin at a first motor driving speed such that, among the plurality of lift pins, any one first lift pin contacts a lower surface of the substrate first and lifts the substrate in the first elevation section;
control a second driving motor configured to drive elevation of a second lift pin at a second motor driving speed being lower than the first motor driving speed such that, among the plurality of lift pins, the second lift pin being closest to a diagonally opposite side of the first lift pin with respect to the center of the support chuck contacts a lower surface of the substrate next to the first lift pin and lifts the substrate; and
control a driving motor configured to drive elevation of the lift pins at a third motor driving speed being lower than the second motor driving speed such that, among the plurality of lift pins, lift pins other than the first lift pin and the second lift pin contact the lower surface of the substrate next to the second lift pin and lifts the substrate.

7. The substrate processing device of claim 6, further comprising:
a bending deformation preventing device configured to apply a load to a circumferential area of the substrate by disposing one or more clamp rings onto the circumferential area of the substrate supported on the support chuck,
wherein the controller is configured to:
predict a stickiness state between the substrate and the support chuck depending on a type of the substrate, a process type of processing the substrate, and loads of the clamp rings, which is applied to the circumferential area of the substrate by the clamp rings; and
differently control the elevation speeds of the plurality of lift pins in the first elevation section by determining the first motor driving speed, the second motor driving speed, and the third motor driving speed depending on the predicted stickiness state.

8. A substrate processing method comprising:
differently controlling elevation speeds of a plurality of lift pins configured to elevate a substrate with respect to a support chuck, for a plurality of elevation sections set with respect to elevation heights of the plurality of lift pins, by controlling a driver through a controller,
wherein the differently controlling of the elevation speeds of the plurality of lift pins includes:
driving the plurality of lift pins at a first elevation speed in, among the plurality of elevation sections, a first elevation section, in which the substrate is lifted from a first height, at which the substrate is positioned on the support chuck, to a preset second height; and
driving the plurality of lift pins at a second elevation speed being higher than the first elevation speed in at least a partial section of a second elevation section, in which the substrate is lifted from the second height to a third height.

9. The substrate processing method of claim 8, wherein the first elevation speed is set to a speed of a half of the second elevation speed or less to solve a stickiness phenomenon, in which the substrate is stuck to an upper surface of the support chuck.

10. The substrate processing method of claim 9, further comprising:
applying a load to a circumferential area of the substrate by disposing one or more clamp rings onto the circumferential area of the substrate supported on the support chuck, by a bending deformation preventing device,
wherein the differently controlling of the elevation speeds of the plurality of lift pins includes:
predicting a stickiness state between the substrate and the support chuck depending on a type of the substrate, a process type of processing the substrate, and loads of the clamp rings, which is applied to the circumferential area of the substrate by the clamp rings, by the controller; and
determining the first elevation speed depending on the predicted stickiness state, and controlling the driver such that the plurality of lift pins are lifted at the first elevation speed in the first elevation section, by the controller.

11. The substrate processing method of claim 9, wherein the differently controlling of the elevation speeds of the plurality of lift pins includes:
differently controlling the first elevation speed for the plurality of lift pins in the first elevation section to solve the stickiness phenomenon, by the controller.

12. The substrate processing method of claim 10, wherein the differently controlling the first elevation speed for the plurality of lift pins includes independently driving the plurality of lift pins by a plurality of driving motors constituting the driver, and motor driving speeds of the plurality of driving motors are differently set in the first elevation section.

13. The substrate processing method of claim 12, wherein the plurality of lift pins include four or more lift pins arranged along a circumferential direction with respect to a center of the support chuck, and
wherein the independently driving of the plurality of lift pins includes:
controlling, among the plurality of driving motors, a first driving motor configured to drive elevation of a first lift pin at a first motor driving speed such that, among the plurality of lift pins, any one first lift pin contacts a lower surface of the substrate first and lifts the substrate in the first elevation section;
controlling a second driving motor configured to drive elevation of a second lift pin at a second motor driving speed being lower than the first motor driving speed such that, among the plurality of lift pins, the second lift pin being closest to a diagonally opposite side of the first lift pin with respect to the center of the support chuck contacts the lower surface of the substrate next to the first lift pin and lifts the substrate; and
controlling a driving motor configured to drive elevation of the lift pins at a third motor driving speed being lower than the second motor driving speed such that, among the plurality of lift pins, lift pins other than the first lift pin and the second lift pin contact the lower surface of the substrate next to the second lift pin and lifts the substrate.

14. The substrate processing method of claim 13, further comprising:
applying a load to a circumferential area of the substrate by disposing one or more clamp rings onto the circumferential area of the substrate supported on the support chuck, by a bending deformation preventing device,
wherein the independently driving of the plurality of lift pins includes:
predicting a stickiness state between the substrate and the support chuck depending on a type of the substrate, a process type of processing the substrate, and loads of the clamp rings, which is applied to the circumferential area of the substrate by the clamp rings; and
differently controlling the elevation speeds of the plurality of lift pins in the first elevation section by determining the first motor driving speed, the second motor driving speed, and the third motor driving speed depending on the predicted stickiness state.
